(19) United States
(12) Patent Application Publication
(10) Pub. No.: US 2025/0216625 A1
(43) Pub. Date: Jul. 3, 2025

(54) SEMICONDUCTOR PACKAGE

(71) Applicant: Samsung Electronics Co., Ltd., Suwon-si (KR)

(72) Inventor: Juhyeon Oh, Suwon-si (KR)

(21) Appl. No.: 19/007,685

(22) Filed: Jan. 2, 2025

(30) Foreign Application Priority Data
Jan. 3, 2024 (KR) 10-2024-0001059

(51) Int. Cl. G02B 6/42; H01L 23/31; H01L 23/48; H01L 25/16; H10B 80/00

(52) U.S. Cl. CPC G02B 6/4206; H01L 23/315; H01L 23/481; H01L 25/167; H10B 80/00

(57) ABSTRACT

A semiconductor package includes a first semiconductor chip, a plurality of second semiconductor chips stacked on the first semiconductor chip, a first molding layer on the first semiconductor chip and surrounding side surfaces of the plurality of second semiconductor chips, a photonic integrated circuit (PIC) chip on an uppermost second semiconductor chip among the plurality of second semiconductor chips, and an electronic integrated circuit (EIC) chip on the PIC chip, wherein an upper surface of the first molding layer is coplanar with an upper surface of the uppermost second semiconductor chip.

### CROSS-REFERENCE TO RELATED APPLICATION

This application is based on and claims priority under 35 U.S.C. § 119 to Korean Patent Application No. 10-2024-0001059, filed on Jan. 3, 2024, in the Korean Intellectual Property Office, the disclosure of which is incorporated by reference herein in its entirety.

### BACKGROUND

Aspects of the inventive concept relate to a semiconductor package, and more particularly, to a semiconductor package including a photonic integrated circuit chip.

The advantages of semiconductor packages are increasingly utilized to improve the functionality of electronic devices and integrate components therein. In a semiconductor package, various integrated circuits, such as memory chips or logic chips, may be mounted on a package substrate. Recently, with increasing data traffic in environments such as data centers and communication infrastructures, there has been ongoing research into semiconductor packages including photonic integrated circuits.

### SUMMARY

Aspects of the inventive concept provide a semiconductor package having a broad bandwidth.

Technical problems to be solved by the inventive concept are not limited to the above description, and other technical problems may be clearly understood by one of ordinary skill in the art from the descriptions provided hereinafter.

According to an aspect of the inventive concept, a semiconductor package includes a first semiconductor chip, a plurality of second semiconductor chips stacked on the first semiconductor chip, a first molding layer on the first semiconductor chip and surrounding side surfaces of the plurality of second semiconductor chips, a photonic integrated circuit (PIC) chip on an uppermost second semiconductor chip among the plurality of second semiconductor chips, and an electronic integrated circuit (EIC) chip on the PIC chip, wherein an upper surface of the first molding layer is coplanar with an upper surface of the uppermost second semiconductor chip.

According to another aspect of the inventive concept, a semiconductor package includes a first semiconductor chip, a plurality of second semiconductor chips stacked on the first semiconductor chip, a first molding layer on an upper portion of the first semiconductor chip and surrounding side surfaces of the plurality of second semiconductor chips, a photonic integrated circuit (PIC) chip on an uppermost second semiconductor chip among the plurality of second semiconductor chips, a second molding layer on the first molding layer and surrounding a portion of the PIC chip, and an electronic integrated circuit (EIC) chip arranged on the PIC chip, wherein an upper surface of the first molding layer is coplanar with an upper surface of the uppermost second semiconductor chip, and wherein the first molding layer contacts the second molding layer.

According to another aspect of the inventive concept, a semiconductor package includes a first semiconductor chip, a plurality of second semiconductor chips stacked on the first semiconductor chip, each including a dynamic random access memory (DRAM) cell, each of the plurality of second semiconductor chips having the same thickness as each other, a first molding layer on an upper portion of the first semiconductor chip and surrounding side surfaces of the plurality of second semiconductor chips, a photonic integrated circuit (PIC) chip on an uppermost second semiconductor chip among the plurality of second semiconductor chips and configured to convert an optical signal into an electrical signal and an electrical signal into an optical signal, a second molding layer on the first molding layer and contacting a portion of the PIC, and an electronic integrated circuit (EIC) chip on the PIC chip and configured to interconnect the PIC chip with the first semiconductor chip, wherein the first semiconductor chip is configured to control the DRAM cell of each of the plurality of second semiconductor chips, wherein the width of the PIC chip is less than a width of the first molding layer, and wherein an upper surface of the first molding layer is coplanar with an upper surface of the uppermost second semiconductor chip.

### BRIEF DESCRIPTION OF THE DRAWINGS

Embodiments of the inventive concept will be more clearly understood from the following detailed description taken in conjunction with the accompanying drawings in which:

FIG. 1 is a schematic plan view of a semiconductor package according to an embodiment;

FIG. 2 is a schematic cross-sectional view of the semiconductor package of FIG. 1 taken along a line A1-A1′ of FIG. 1;

FIG. 3 is a schematic enlarged view illustrating a region EX1 of the semiconductor package of FIG. 2;

FIG. 4 is a schematic cross-sectional view of a semiconductor package according to an embodiment, taken along the line A1-A1′ of FIG. 1;

FIG. 5 is a schematic cross-sectional view of a semiconductor package according to an embodiment, taken along the line A1-A1′ of FIG. 1;

FIG. 6 is a schematic cross-sectional view of a semiconductor package according to an embodiment, taken along the line A1-A1′ of FIG. 1;

FIG. 7 is a schematic cross-sectional view of a semiconductor package according to an embodiment, taken along the line A1-A1′ of FIG. 1;

FIG. 8 is a schematic plan view of a semiconductor package according to an embodiment;

FIG. 9 is a schematic cross-sectional view of the semiconductor package of FIG. 8 taken along a line A2-A2′ of FIG. 8;

FIG. 10 is a schematic cross-sectional view of a semiconductor package according to an embodiment, taken along the line A1-A1′ of FIG. 1;

FIG. 11 is a schematic plan view of a semiconductor package according to an embodiment.

FIG. 12 is a schematic cross-sectional view of the semiconductor package of FIG. 11 taken along a line A3-A3′ of FIG. 11;

FIG. 13 is a schematic enlarged view illustrating a region EX2 of the semiconductor package of FIG. 12;

FIG. 14 is a schematic plan view of a semiconductor package according to an embodiment; and

FIG. 15 is a schematic cross-sectional view of the semiconductor package of FIG. 14 taken along a line A4-A4′ of FIG. 14.

### DETAILED DESCRIPTION OF THE EMBODIMENTS

As the disclosure allows for various changes and numerous embodiments, particular embodiments will be shown in the drawings and described in detail in the written description. However, it is not intended to limit the present embodiments to specific embodiments.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

The disclosed “layers” may each be a single homogeneous layer (formed of the same base material throughout). For example, the disclosed “layers” may each be formed with a single corresponding process (e.g., in situ-in a chamber without vacuum break to the chamber).

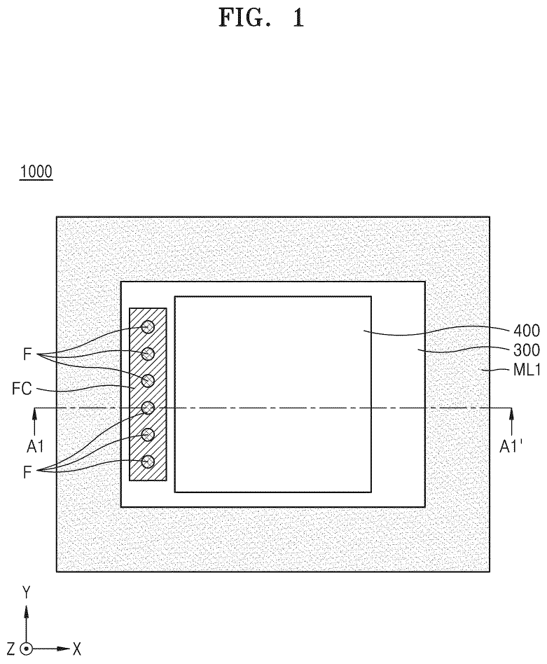

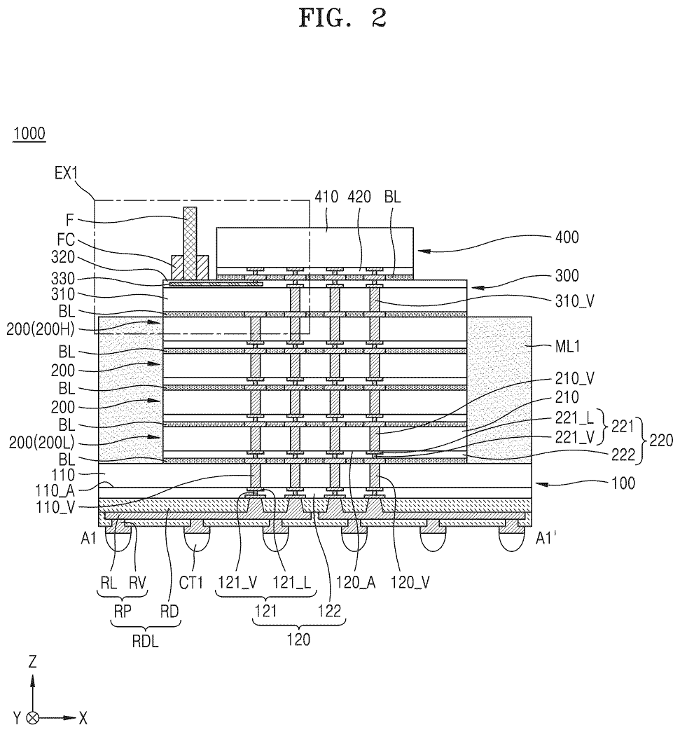

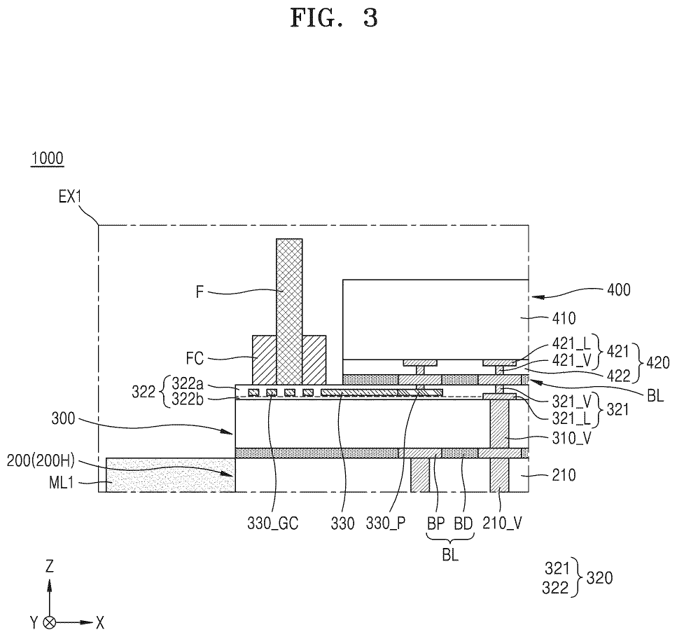

FIG. 1 is a schematic plan view of a semiconductor package 1000 according to an embodiment. FIG. 2 is a schematic cross-sectional view of the semiconductor package 1000 of FIG. 1 taken along a line A1-A1′ of FIG. 1. FIG. 3 is a schematic enlarged view illustrating a region EX1 of the semiconductor package 1000 of FIG. 2.

Referring to FIGS. 1 to 3, the semiconductor package 1000 may include a first semiconductor chip 100, a plurality of second semiconductor chips 200, a first molding layer ML1, a photonic integrated circuit (PIC) chip 300, and an electronic integrated circuit (EIC) chip 400.

Hereinafter, unless otherwise specifically defined, a direction parallel to an upper surface of the first semiconductor chip 100 is defined as a first horizontal direction (an X direction), a direction perpendicular to the upper surface of the first semiconductor chip 100 is defined as a vertical direction (a Z direction), and a direction perpendicular to the first horizontal direction (the X direction) and the vertical direction (the Z direction) is defined as a second horizontal direction (a Y direction). A horizontal direction is defined as any combination of the first horizontal direction (the X direction) and the second horizontal direction (the Y direction).

The first semiconductor chip 100 may include a first substrate 110, a first through via 110_V, and a first wiring structure 120. The first substrate 110 may include an active surface 110_A, on which a plurality of individual devices are placed, and an inactive surface opposite to the active surface 110_A. The first wiring structure 120 may be on the active surface 110_A of the first substrate 110. The first through via 110_V may extend from the inactive surface of the first substrate 110 to the active surface 110_A thereof and may be electrically connected to the first wiring structure 120.

The first wiring structure 120 may include a first wiring pattern 121 and a first wiring insulating layer 122 surrounding the first wiring pattern 121. The first wiring pattern 121 may include a first wiring line 121_L extending in the horizontal direction and a first wiring via 121_V extending from the first wiring line 121_L in the vertical direction (the Z direction). The first wiring pattern 121 may be electrically connected to the individual devices of the first semiconductor chip 100.

In some embodiments, a redistribution layer RDL may be further included on a lower surface of the first wiring structure 120. The redistribution layer RDL may include a redistribution pattern RP and a redistribution insulating layer RD surrounding the redistribution pattern RP. The redistribution pattern RP may include a redistribution line RL extending in the horizontal direction and a redistribution via RV extending from the redistribution line RL in the vertical direction (the Z direction). The redistribution line RL may be arranged on at least one of the upper surface and the lower surface of the redistribution insulating layer RD or arranged inside the redistribution insulating layer RD. The redistribution via RV may penetrate the redistribution insulating layer RD and be connected to a portion of the redistribution line RL.

In some embodiments, an external connection terminal CT1 may be attached to the lower surface of the first wiring structure 120 or the lower surface of the redistribution layer RDL. The external connection terminal CT1 may be configured to electrically and physically connect the semiconductor package 1000 to an external device in/on which the semiconductor package 1000 is mounted. The external connection terminal CT1 may be formed from, for example, a solder ball or a solder bump.

Each of the second semiconductor chips 200 may include a second substrate 210, a second through via 210_V, and a second wiring structure 220. The second substrate 210 may include an active surface, on which a plurality of individual devices are placed, and an inactive surface opposite to the active surface. The second wiring structure 220 may be on the active surface of the second substrate 210. The second through via 210_V may extend from the inactive surface of the second substrate 210 to the active surface of the second substrate 210 and may be electrically connected to the second wiring structure 220.

The second wiring structure 220 may include a second wiring pattern 221 and a second wiring insulating layer 222 surrounding the second wiring pattern 221. The second wiring pattern 221 may include a second wiring line 221_L extending in the horizontal direction and a second wiring via 221_V extending from the second wiring line 221_L in the vertical direction (the Z direction). The second wiring pattern 221 may be electrically connected to the individual devices of each of the second semiconductor chips 200.

In some embodiments, a thickness of each second semiconductor chip 200 in a vertical direction may be between about 20 μm and about 80 μm. The thicknesses H_200 of each second semiconductor chip 200 may be substantially the same.

The first substrate 110 and the second substrate 210 may each include, for example, a semiconductor material such as silicon (Si). Alternatively, the first substrate 110 and the second substrate 210 may each include a semiconductor material, such as Ge.

The individual devices of the first semiconductor chip 100 may include various microelectronic devices, for example, a metal-oxide-semiconductor field effect transistor (MOSFET) such as a complementary metal-insulator-semiconductor (CMOS) transistor, an image sensor such as system large scale integration (LSI) or a CMOS imaging sensor (CIS), a micro-electro-mechanical system (MEMS), active elements, passive elements, and the like.

The individual devices of each second semiconductor chip 200 may include a memory cell. For example, the memory cell may be a non-volatile memory cell, such as flash memory, phase-change random access memory (PRAM), magneto-resistive random access memory (MRAM), ferroelectric random access memory (FeRAM), or resistive random access memory (RRAM). In some embodiments, the memory cell may be a volatile memory cell, such as dynamic random access memory (DRAM) or static random access memory (SRAM).

FIG. 2 illustrates that the semiconductor package 1000 includes four second semiconductor chips 200, but embodiments are not limited thereto. The semiconductor package 1000 may include two or more second semiconductor chips 200.

The second semiconductor chips 200 may be sequentially stacked on the first semiconductor chip 100. For convenience of explanation, a second semiconductor chip 200 that is lowermost among the second semiconductor chips 200 may be referred to as a lowermost second semiconductor chip 200L and a second semiconductor chip 200 that is uppermost among the second semiconductor chips 200 may be referred to as an uppermost second semiconductor chip 200H.

In some embodiments, bonding layers BL may be placed between the first semiconductor chip 100 and the lowermost second semiconductor chip 200L and between adjacent second semiconductor chips 200. The bonding layer BL may include a bonding pad BP and a bonding insulating layer BD surrounding the bonding pad BP. For example, the first semiconductor chip 100 and the lowermost second semiconductor chip 200L may be electrically connected to the second semiconductor chips 200 by the bonding layers BL.

In some embodiments, the bonding pad BP of the bonding layer BL arranged between the first semiconductor chip 100 and the lowermost second semiconductor chip 200L may be formed as an upper pad of the first semiconductor chip 100 that is diffusion-bonded to a lower pad of the lowermost second semiconductor chip 200L through heat. In the process of forming the bonding pad BP, the bonding insulating layer BD may be formed as an insulating layer surrounding the upper pad of the first semiconductor chip 100 that is diffusion-bonded to an insulating layer surrounding the lower pad of the lowermost second semiconductor chip 200L through heat.

For example, the process of forming the bonding layer BL located between adjacent second semiconductor chips 200 may be substantially the same as the process of forming the bonding layer BL located between the first semiconductor chip 100 and the lowermost second semiconductor chip 200L.

That is, the first semiconductor chip 100 and the lowermost second semiconductor chip 200L may be electrically coupled to the second semiconductor chips 200 through hybrid bonding. However, embodiments are not limited thereto. The first semiconductor chip 100 and the lowermost second semiconductor chip 200L may be electrically connected to the second semiconductor chips 200 by connection terminals, such as solder balls, or an adhesive film, such as an anisotropic conductive film (ACF) or a non-conductive film (NCF).

In some embodiments, the first semiconductor chip 100 may be a buffer chip including a serial-parallel conversion circuit and used to control the second semiconductor chips 200, and the second semiconductor chips 200 may each be a memory chip including memory cells. For example, the second semiconductor chips 200 may each include a DRAM memory cell, and the first semiconductor chip 100 may be configured to control the DRAM memory cell of each second semiconductor chip 200.

For example, the semiconductor package 1000 including the first semiconductor chip 100 and the second semiconductor chips 200 may be High Bandwidth Memory (HBM), the first semiconductor chip 100 may be referred to as an HBM controller die, and the second semiconductor chips 200 may each be referred to as a DRAM die.

The first molding layer ML1 may be on the first semiconductor chip 100 and surround side surfaces of the second semiconductor chips 200. The first molding layer ML1 may protect the first semiconductor chip 100 and the second semiconductor chips 200 from the outside.

In some embodiments, the upper surface of the first molding layer ML1 may be coplanar with the upper surface of the uppermost second semiconductor chip 200H. Terms such as “same,” “planar,” “coplanar,” “parallel,” and “perpendicular,” as used herein encompass identically or near identically including variations that may occur resulting from standard manufacturing processes. The term “substantially” may be used herein to emphasize this meaning, unless the context or other statements indicate otherwise. For example, the vertical level of the upper surface of the first molding layer ML1 may be the same as the vertical level of the upper surface of the uppermost second semiconductor chip 200H. In the present specification, the term “vertical level” refers to a distance from the lower surface of the first semiconductor chip 100.

In some embodiments, the first molding layer ML1 may include epoxy resin, polyimide resin, or the like. The first molding layer ML1 may include, for example, an epoxy mold compound (EMC).

The PIC chip 300 and the EIC chip 400 may be collectively referred to as an optic engine. The optic engine may convert an optical signal into an electrical signal and an electrical signal into an optical signal. For example, the optic engine may exchange electrical signals with the first semiconductor chip 100 and the second semiconductor chips 200 and optical signals with optical fiber F.

The PIC chip 300 may be on the second semiconductor chips 200. The PIC chip 300 may be on the uppermost second semiconductor chip 200H and electrically connected to the uppermost second semiconductor chip 200H by the bonding layer BL.

In some embodiments, the bonding layer BL may be arranged between the PIC chip 300 and the uppermost second semiconductor chip 200H. The bonding layer BL between the PIC chip 300 and the uppermost second semiconductor chip 200H may be substantially the same as the bonding layer BL between the first semiconductor chip 100 and the lowermost second semiconductor chip 200L.

In some embodiments, the upper surface of the PIC chip 300 may be at a higher level than the upper surface of the first molding layer ML1. For example, the vertical level of the upper surface of the PIC chip 300 may be higher than that of the upper surface of the first molding layer ML1.

In some embodiments, the width of the PIC chip 300 may be less than that of the first molding layer ML1. For example, the side surface of the PIC chip 300 may be on the upper surface of the first molding layer ML1.

In some embodiments, the widths of the second semiconductor chips 200 may be the same, and the side surfaces of the second semiconductor chips 200 may be coplanar with each other. The width of the PIC chip 300 may be the same as the widths of the second semiconductor chips 200. For example, the side surface of the PIC chip 300 may be coplanar with the side surfaces of the second semiconductor chips 200.

The PIC chip 300 may include a third substrate 310, a third wiring structure 320, and a plurality of waveguides 330. For example, the third wiring structure 320 and the waveguides 330 may be on an upper surface of the third substrate 310. For example, the waveguides 330 may be in the PIC chip 300 adjacent to an upper surface of the PIC chip 300. For example, the third substrate 310 may include a third through via 310_V extending from an upper surface of the third substrate 310 to a lower surface thereof.

The third substrate 310 may include a semiconductor material, such as Si. Alternatively, the third substrate 310 may include a semiconductor material, such as Ge.

The third wiring structure 320 may include a third wiring pattern 321 and a third wiring insulating layer 322 surrounding the third wiring pattern 321. The third wiring pattern 321 may include a third wiring line 321_L extending in the horizontal direction and a third wiring via 321_V extending from the third wiring line 321_L in the vertical direction (the Z direction). The third wiring pattern 321 may be electrically connected to the third through via 310_V.

In some embodiments, the third wiring insulating layer 322 may be separated into a lower wiring insulating layer 322b and an upper wiring insulating layer 322a. In some embodiments, the lower wiring insulating layer 322b may be an oxide layer including silicon oxide or the like. The upper wiring insulating layer 322a may be one or more dielectric layers including silicon oxide, silicon nitride, or a combination thereof. In some embodiments, the lower wiring insulating layer 322b may include the same material as the upper wiring insulating layer 322a.

The waveguides 330 may each be a patterned silicon layer and horizontally extend on the lower wiring insulating layer 322b. For example, the waveguides 330 may be buried in the third wiring insulating layer 322. For example, the waveguides 330 may be on the lower wiring insulating layer 322b and covered by the upper wiring insulating layer 322a. In some embodiments, the waveguides 330 may each be a silicon waveguide, and the third wiring insulating layer 322 may be a buried oxide (BOX) layer. In some embodiments, the waveguides 330 may be covered by an oxide layer distinguished from the third wiring insulating layer 322.

In some embodiments, at least some of the waveguides 330 may not overlap the EIC chip 400 in the vertical direction (the Z direction). For example, at least a portion of each of the waveguides 330 may not overlap the EIC chip 400 in the vertical direction (the Z direction) In some embodiments, the waveguides 330 may be configured to receive/transmit optical signals in a region of the waveguides 330 that does not overlap the EIC chip 400 in the vertical direction (the Z direction).

For example, each waveguide 330 may include a grating coupler 330_GC optically connected to the optical fiber F, and the grating coupler 330_GC may be located in the region of the waveguides 330 that does not overlap the EIC chip 400 in the vertical direction (the Z direction).

Each waveguide 330 may transmit an optical signal. For example, the waveguides 330 may provide a path through which optical signals input to the grating coupler 330_GC move to a photonic component 330_P.

The waveguides 330 may be connected to the photonic component 330_P. For example, a surface on which the photonic component 330_P is located may be referred to as an active surface of the third substrate 310. The photonic component 330_P may convert an optical signal into an electrical signal and an electrical signal into an optical signal. In some embodiments, the photonic component 330_P may include a photodetector, laser diodes or other types of light emitting diodes, and a modulator.

In the process whereby an optical signal is input to the PIC chip 300, the photonic component 330_P (e.g., a photodetector) may detect the optical signal that is input to the PIC chip 300. The PIC chip 300 may detect the optical signal that is input through the photodetector and may convert the same into an electrical signal.

In the process whereby the PIC chip 300 outputs the optical signal, the EIC chip 400 may transmit the electrical signal to the photonic component 330_P (e.g., a modulator) of the PIC chip 300. The modulator may input a signal, which corresponds to an electrical signal transmitted from the EIC chip 400, to light emitted from laser diodes which may also be included in the photonic component 330_P. The PIC chip 300 may convert an electrical signal into an optical signal through the modulator and the laser diodes.

The EIC chip 400 may be on the PIC chip 300. The EIC chip 400 may be configured to interconnect the PIC chip 300 with the first semiconductor chip 100. For example, the EIC chip 400 may convert the electrical signal, which is converted by the PIC chip 300, to match with (e.g., be readable by) the first semiconductor chip 100.

In some embodiments, the bonding layer BL may be arranged between the EIC chip 400 and the PIC chip 300. The bonding layer BL between the EIC chip 400 and the PIC chip 300 may be substantially the same as the bonding layer BL between the first semiconductor chip 100 and the lowermost second semiconductor chip 200L.

However, embodiments are not limited thereto, and the EIC chip 400 may be electrically connected to the PIC chip 300 by a connection terminal, such as a solder ball or a conductive film, such as an ACF or an NCF.

In some embodiments, the width of the EIC chip 400 may be less than that of the PIC chip 300. For example, the side surface of the EIC chip 400 may be on the upper surface of the PIC chip 300. A portion of the PIC chip 300 may not be covered by the EIC chip 400. That is, a portion of the PIC chip 300 may not vertically overlap the EIC chip 400.

In some embodiments, a portion of the upper surface of the PIC chip 300 may not be covered by the EIC chip 400 and may be externally exposed. The grating couplers 330_GC of the waveguides 330 of the PIC chip 300 may be in a region of the upper surface of the PIC chip 300 that is externally exposed.

The EIC chip 400 may include a fourth substrate 410 and a fourth wiring structure 420. The fourth substrate 410 of the EIC chip 400 may include an active surface and an inactive surface opposite thereto. The fourth wiring structure 420 may be formed on the active surface of the fourth substrate 410.

The fourth substrate 410 may include a semiconductor material, such as Si. Alternatively, the fourth substrate 410 may include a semiconductor material, such as Ge.

In some embodiments, the EIC chip 400 may include a plurality of individual devices used to interface the EIC chip 400 with the PIC chip 300. The individual devices of the EIC chip 400 may be arranged on the active surface of the fourth substrate 410. For example, the EIC chip 400 may include CMOS drivers, trans-impedance amplifiers, and the like to perform a function of controlling high-frequency signaling of the PIC chip 300.

The fourth wiring structure 420 may include a fourth wiring pattern 421 and a fourth wiring insulating layer 422 surrounding the fourth wiring pattern 421. The fourth wiring pattern 421 may include a fourth wiring line 421_L extending in the horizontal direction and a fourth wiring via 421_V extending from the fourth wiring line 421_L in the vertical direction (the Z direction). The fourth wiring pattern 421 may be electrically connected to the individual devices of the EIC chip 400.

In some embodiments, the EIC chip 400 may be arranged on the PIC chip 300 to make the active surface of the fourth substrate 410 face the PIC chip 300. For example, the EIC chip 400 may be arranged on the PIC chip 300 in a face-down manner.

In some embodiments, the semiconductor package 1000 may further include a plurality of optical fibers F and an optical fiber lead FC. The optical fibers F may be configured to transmit optical signals from an external source of the semiconductor package 1000 to the waveguides 330 of the PIC chip 300.

The optical fibers F may be arranged above different grating couplers 330_GC, and the optical fiber lead FC may surround the optical fibers F and fix the optical fibers F onto the PIC chip 300. For example, each optical fiber F may be arranged above, and may correspond to, a respective grating coupler 330_GC. In some embodiments, for example, the optical fibers F and the optical fiber lead FC may be collectively referred to as an optical fiber array unit.

In some embodiments, the optical fibers F and the optical fiber lead FC may be arranged on the PIC chip 300, and the optical fibers F may be horizontally spaced apart from the EIC chip 400. For example, the optical fibers F and the optical fiber lead FC may be in a region of the upper surface of the PIC chip 300 that is not covered by the EIC chip 400.

In some embodiments, the optical fibers F may be arranged on the upper surface of the PIC chip 300 along an edge of the PIC chip 300. For example, the optical fibers F may be arranged in a line or a zigzag form along a side of the upper surface of the PIC chip 300. In some embodiments, the optical fibers F may be arranged to the side of (e.g., next to in the horizontal direction) the EIC chip 400.

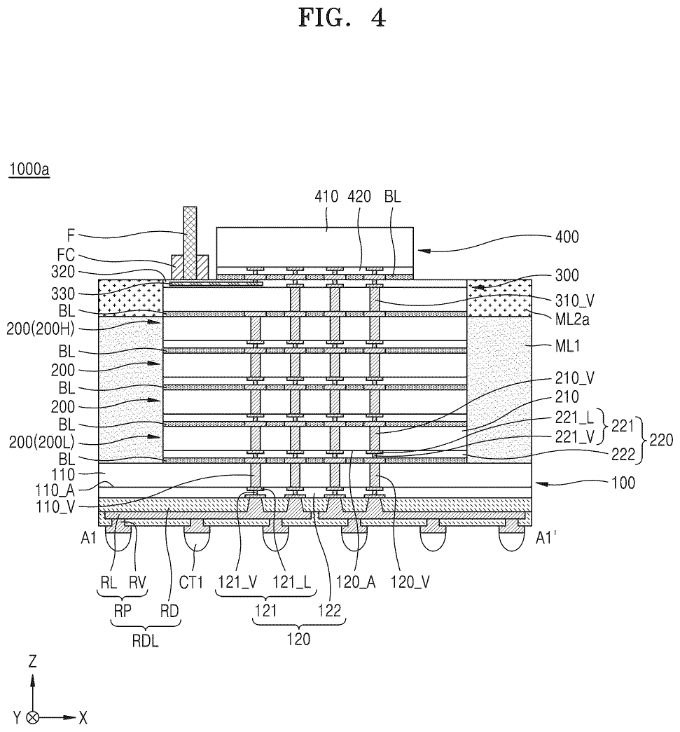

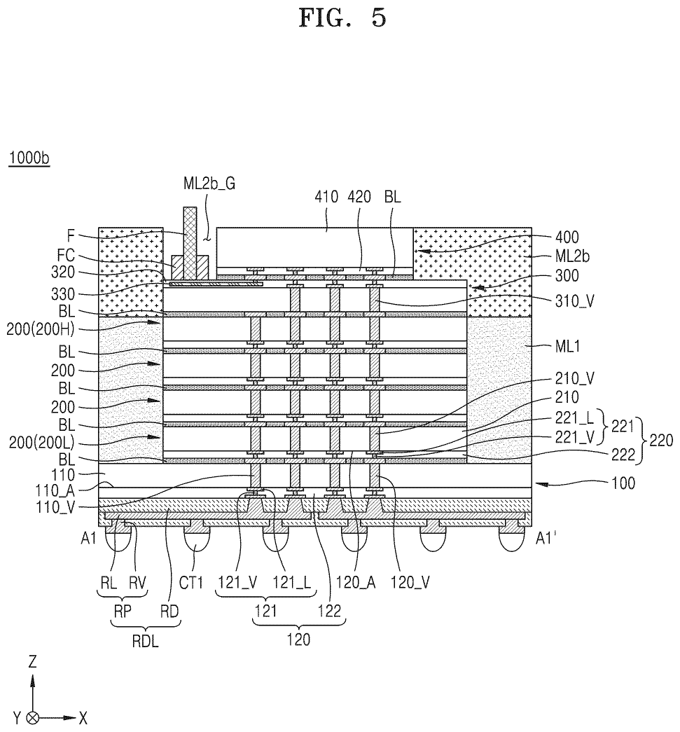

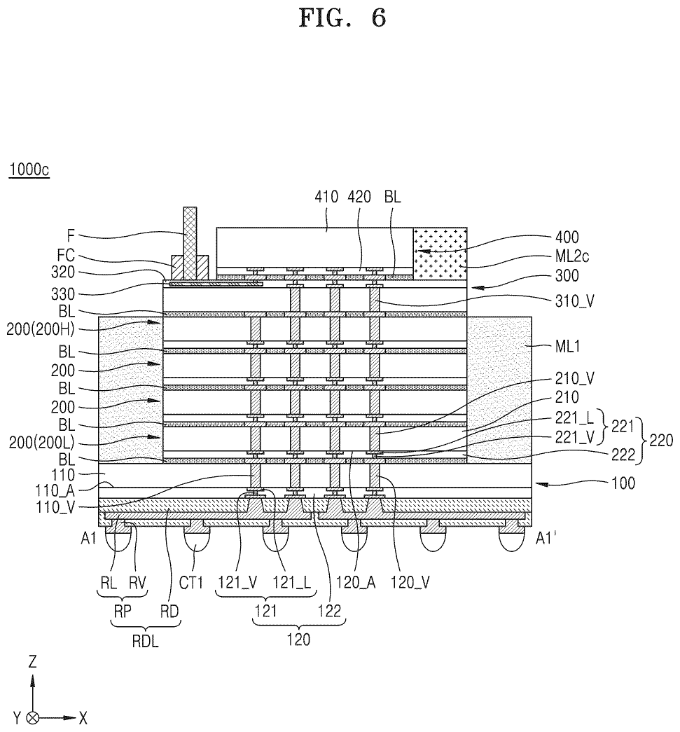

FIG. 4 is a schematic cross-sectional view of a semiconductor package 1000a according to an embodiment, taken along the line A1-A1′ of FIG. 1. FIG. 5 is a schematic cross-sectional view of a semiconductor package 1000b according to an embodiment, taken along the line A1-A1′ of FIG. 1. FIG. 6 is a schematic cross-sectional view of a semiconductor package 1000c according to an embodiment, taken along the line A1-A1′ of FIG. 1.

Most of the components forming the semiconductor packages 1000a to 1000c described below and the materials of the components are substantially the same as or similar to those described above with reference to FIG. 2. Therefore, for convenience of explanation, the differences between the semiconductor packages 1000a to 1000c of FIGS. 4 to 6 and the semiconductor package 1000 of FIG. 2 are mainly described.

Referring to FIG. 4, the semiconductor package 1000a may further include a second molding layer ML2a. The second molding layer ML2a may be on the first molding layer ML1 and in contact with at least a portion of the PIC chip 300. An interface may exist between the second molding layer ML2a and the first molding layer ML1. For example, the first molding layer ML1 may contact the second molding layer ML2a.

For example, during the manufacturing processes of the semiconductor package 1000a, there is a difference in curing timings between the first molding layer ML1 and the second molding layer ML2a, and thus, there may be an interface between the first molding layer ML1 and the second molding layer ML2a even though the first molding layer ML1 may be formed of the same material as the second molding layer ML2a. However, the inventive concept is not limited thereto, and the first molding layer ML1 may include a material different from the material of the second molding layer ML2a.

The second molding layer ML2a may surround the side surface of the PIC chip 300. For example, the upper surface of the second molding layer ML2a may be coplanar with the upper surface of the PIC chip 300. The second molding layer ML2a may protect the PIC chip 300 from the outside.

In some embodiments, the width of the second molding layer ML2a may be the same as that of the first molding layer ML1. The side surface of the second molding layer ML2a may be coplanar with the side surface of the first molding layer ML1. The height of the second molding layer ML2a may be the same as the height of the PIC chip 300.

In some embodiments, after the PIC chip 300 is mounted on the uppermost second semiconductor chip 200H, the second molding layer ML2a may be formed to cover the PIC chip 300. Then, the upper portion of the second molding layer ML2a may be removed so that an upper surface of the PIC chip 300 is exposed. Accordingly, the vertical level of the upper surface of the second molding layer ML2a may be substantially the same as the vertical level of the upper surface of the PIC chip 300. In addition, the surface roughness of the upper surface of the second molding layer ML2a may be the same as the surface roughness of the upper surface of the PIC chip 300.

However, embodiments are not limited thereto. The optic engine may first be produced by forming the second molding layer ML2 to surround the side surface of the PIC chip 300 and then mounting the EIC chip 400 on the PIC chip 300, and then the optic engine may be mounted on the uppermost second semiconductor chip 200H and the first molding layer ML1.

Referring to FIG. 5, the semiconductor package 1000b may further include a second molding layer ML2b. The second molding layer ML2b may be on the first molding layer ML1 and in contact with at least a portion of the PIC chip 300. An interface may exist between the second molding layer ML2b and the first molding layer ML1. For example, the first molding layer ML1 may contact the second molding layer ML2b.

The second molding layer ML2b may surround the PIC chip 300 and the EIC chip 400. The upper surface of the second molding layer ML2b may be coplanar with the upper surface of the EIC chip 400. The second molding layer ML2b may protect the PIC chip 300 and the EIC chip 400 from the outside.

The second molding layer ML2b may include a first groove ML2b_G extending from the upper surface of the second molding layer ML2b to the inside of the second molding layer ML2b. For example, the first groove ML2b_G may extend from the upper surface of the second molding layer ML2b toward a lower surface of the second molding layer ML2b For example, the first groove ML2b_G may be positioned in an upper portion of a region in which the waveguides 330 are located that does not overlap the EIC chip 400. For example, the optical fibers F and the optical fiber lead FC may be mounted in the first groove ML2b_G.

In some embodiments, the first groove ML2b_G may be positioned above the waveguides 330 of the PIC chip 300. The first groove ML2b_G may be located above the grating coupler (330_GC, see FIG. 3) of the waveguides 330 of the PIC chip 300 such that the upper surface of the grating coupler may be exposed.

In some embodiments, when the optic engine is manufactured before being mounted on the uppermost second semiconductor chip 200H, the second molding layer ML2b may be formed to surround the PIC chip 300 and the EIC chip 400. Then, the first groove ML2b_G may be formed in the second molding layer ML2b to externally expose a region of the upper surface of the PIC chip 300, where the optical fibers F and the optical fiber lead FC are to be formed.

For example, the shape of the first groove ML2b_G of the second molding layer ML2b is not limited to that illustrated in FIG. 5 and may vary to correspond to the optical fibers F and the optical fiber lead FC.

Referring to FIG. 6, the semiconductor package 1000c may further include a second molding layer ML2c. The second molding layer ML2c may be in contact with at least a portion of the PIC chip 300.

The second molding layer ML2c may be on the PIC chip 300 and cover a portion of the side surface of the EIC chip 400. The upper surface of the second molding layer ML2c may be coplanar with the upper surface of the EIC chip 400.

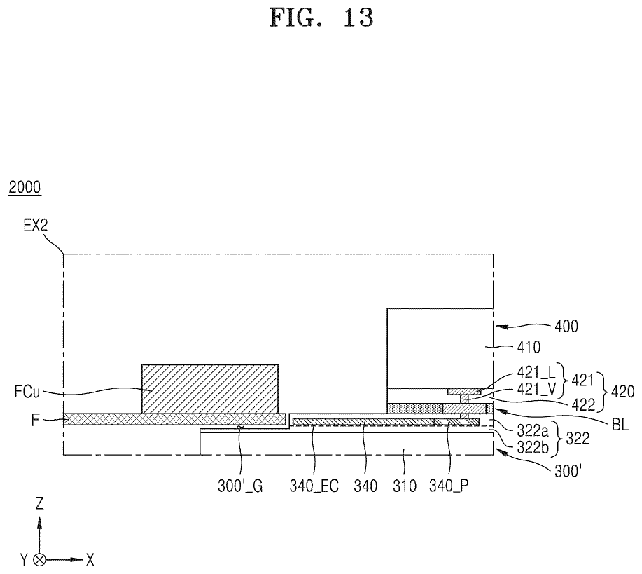

The second molding layer ML2c may not cover a region of the upper surface of the PIC chip 300, where a coupler of the PIC chip 300 is located. For example, the second molding layer ML2c may include a groove in an upper portion of the coupler of the PIC chip 300. For example, the coupler of the PIC chip 300 may be one of an edge coupler (340_EC, see FIG. 13) and the grating coupler (330_GC, see FIG. 3).

The second molding layer ML2c may not be in contact with the first molding layer ML1. For example, the lower surface of the second molding layer ML2c may be spaced apart from the upper surface of the first molding layer ML1. The side surface of the PIC chip 300 and the upper surface of the first molding layer ML1 may be exposed to the outside.

For example, when the optic engine is manufactured before being mounted on the uppermost second semiconductor chip 200H, the second molding layer ML2c may be formed on the PIC chip 300 to surround the EIC chip 400. Then, a portion of the second molding layer ML2c may be removed to externally expose a region of the upper surface of the PIC chip 300, where the optical fibers F and the optical fiber lead FC are to be installed.

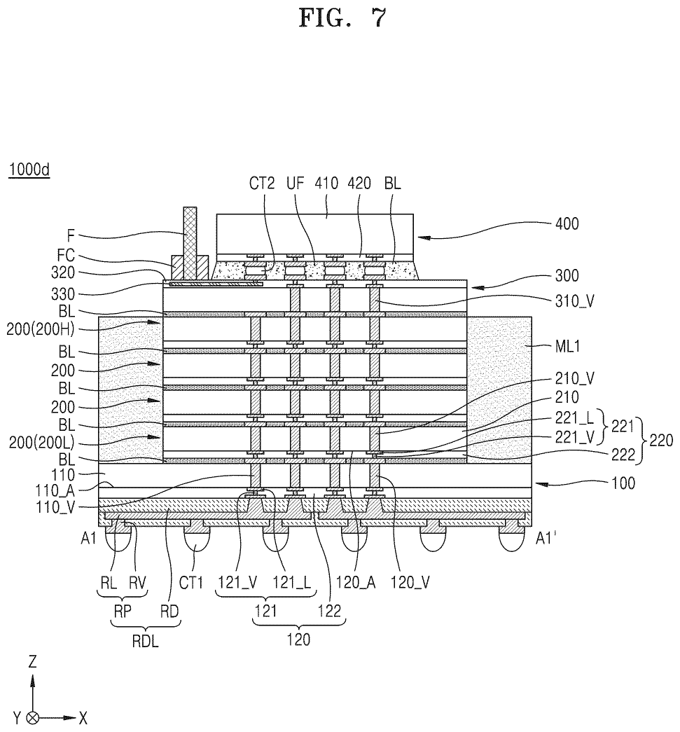

FIG. 7 is a schematic cross-sectional view of a semiconductor package 1000d according to an embodiment, taken along the line A1-A1′ of FIG. 1.

Most of the components forming a semiconductor package 1000d described below and the materials of the components are substantially the same as or similar to those described above with reference to FIG. 2. Therefore, for convenience of explanation, the differences between the semiconductor package 1000d of FIG. 7 and the semiconductor package 1000 of FIG. 2 are mainly described.

Referring to FIG. 7, the semiconductor package 1000d may further include a connection terminal CT2 and an underfill layer UF arranged between the PIC chip 300 and the EIC chip 400.

For example, the connection terminal CT2 may be arranged between the third wiring structure 320 of the PIC chip 300 and the fourth wiring structure 420 of the EIC chip 400 and may electrically connect the PIC chip 300 to the EIC chip 400.

The underfill layer UF may be arranged between the PIC chip 300 and the EIC chip 400 and surround the connection terminal CT2. The underfill layer UF may be arranged between the connection terminals CT2 and protect the connection terminals CT2 from the outside.

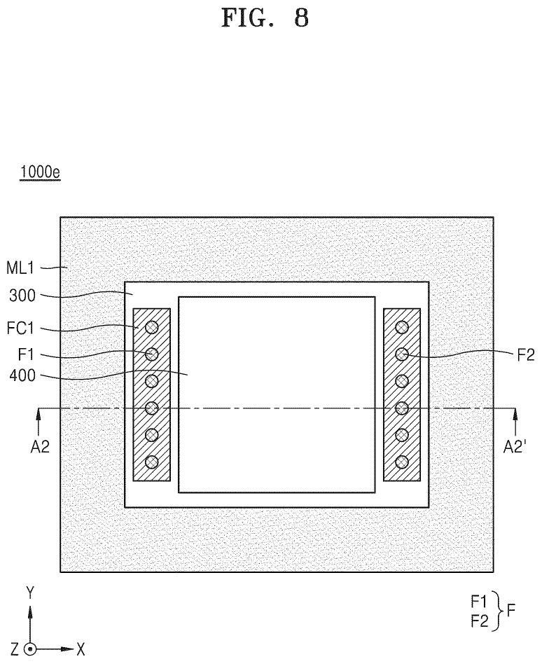

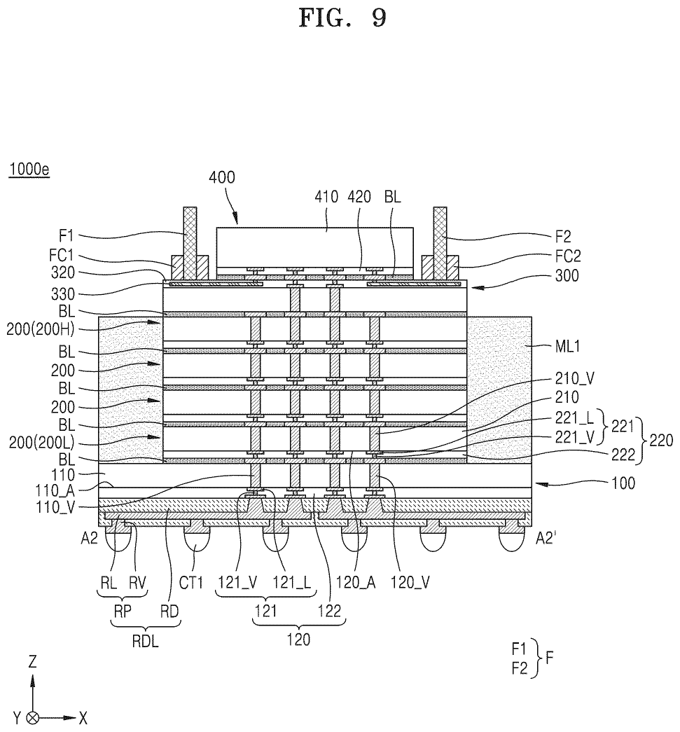

FIG. 8 is a schematic plan view of a semiconductor package 1000e according to an embodiment. FIG. 9 is a schematic cross-sectional view of the semiconductor package 1000e of FIG. 8 taken along a line A2-A2′ of FIG. 8.

Most of the components forming the semiconductor package 1000e described below and the materials of the components are substantially the same as or similar to those described above with reference to FIG. 2. Therefore, for convenience of explanation, the differences between the semiconductor package 1000e of FIG. 9 and the semiconductor package 1000 of FIG. 2 are mainly described.

Referring to FIGS. 8 and 9, the semiconductor package 1000e may include optical fibers F. The optical fibers F may include a first optical fiber F1 and a second optical fiber F2. The first optical fiber F1 may be spaced apart from the second optical fiber F2 with the EIC chip 400 therebetween.

In some embodiments, when the PIC chip 300 includes a first side surface (e.g., a surface extending in a vertical plane) and a second side surface opposite to the first side surface, the first optical fiber F1 may be located near the first side surface of the PIC chip 300, and the second optical fiber F2 may be located near the second side surface of the PIC chip 300. For example, the first optical fiber F1 may be closer to a first edge of the PIC chip 300 than the EIC chip 400 is, and the second optical fiber F2 may be closer to a second edge of the PIC chip 300 than the EIC chip 400 is, the second edge being opposite to the first edge.

In some embodiments, the optical fibers F may be categorized into a first group and a second group, wherein the first group is located near the first side surface of the PIC chip 300 and the second group is located near the second side surface of the PIC chip 300. The first optical fiber F1 may be included in the first group, and the second optical fiber F2 may be included in the second group.

In some embodiments, the semiconductor package 1000e may further include a first optical fiber lead FC1 and a second optical fiber lead FC2. The first optical fiber lead FC1 may fix optical fibers included in the first group among the optical fibers F, and the second optical fiber lead FC2 may fix optical fibers included in the second group among the optical fibers F.

Waveguides of the PIC chip 300 may include a first waveguide and a second waveguide. Each of the first waveguide and the second waveguide may be optically connected to one of the optical fibers. For example, the first waveguide may be optically connected to the first optical fiber F1 and the second waveguide may be optically connected to the second optical fiber F2.

In some embodiments, a grating coupler of the first waveguide may be spaced apart from a grating coupler of the second waveguide with an EIC chip therebetween. The grating coupler of the first waveguide may be located under the first optical fiber and the grating coupler of the second waveguide may be located under the second optical fiber.

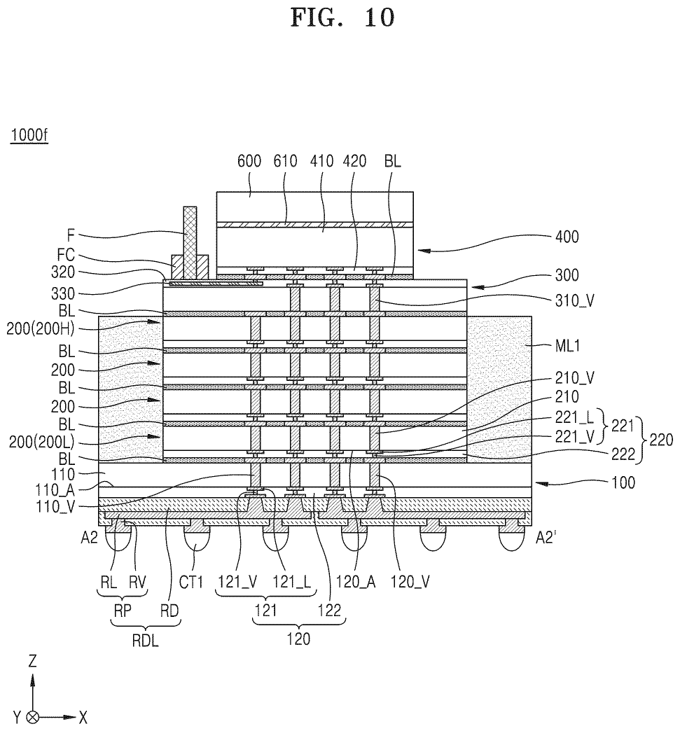

FIG. 10 is a schematic cross-sectional view of a semiconductor package 1000f according to an embodiment, taken along the line A1-A1′ of FIG. 1.

Most of the components forming the semiconductor package 1000f described below and the materials of the components are substantially the same as or similar to those described above with reference to FIG. 2. Therefore, for convenience of explanation, the differences between the semiconductor package 1000f of FIG. 10 and the semiconductor package 1000 of FIG. 2 are mainly described.

Referring to FIG. 10, the semiconductor package 1000f may further include a heat sink 600.

The heat sink 600 may be configured to emit heat generated by the EIC chip 400. In some embodiments, the heat sink 600 may have a planar shape. The heat sink 600 may include a thermally conductive material with high thermal conductivity. For example, the heat sink 600 may include metal, such as copper (Cu) or aluminum (Al), or a carbonaceous material, such as graphene, graphite, and/or a carbon nanotube. However, the materials of the heat sink 600 are not limited thereto. In some embodiments, the heat sink 600 may include a single metal layer or a plurality of stacked metal layers.

The heat sink 600 may be attached to the EIC chip 400. For example, the heat sink 600 may be attached to the upper surface of the EIC chip 400 through a thermal interface material (TIM) layer 610. As the heat sink 600 directly contacts the EIC chip 400 through the TIM layer 610, heat dissipation characteristics may be improved.

The TIM layer 610 may include a material that is thermally conductive and electrically insulative. For example, the TIM layer 610 may include a polymer including metal powder, such as silver (Ag) or Cu, thermal grease, white grease, or a combination thereof.

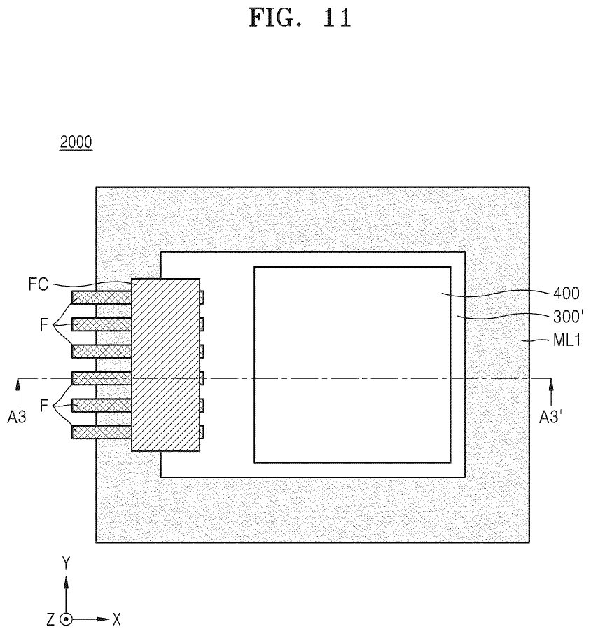

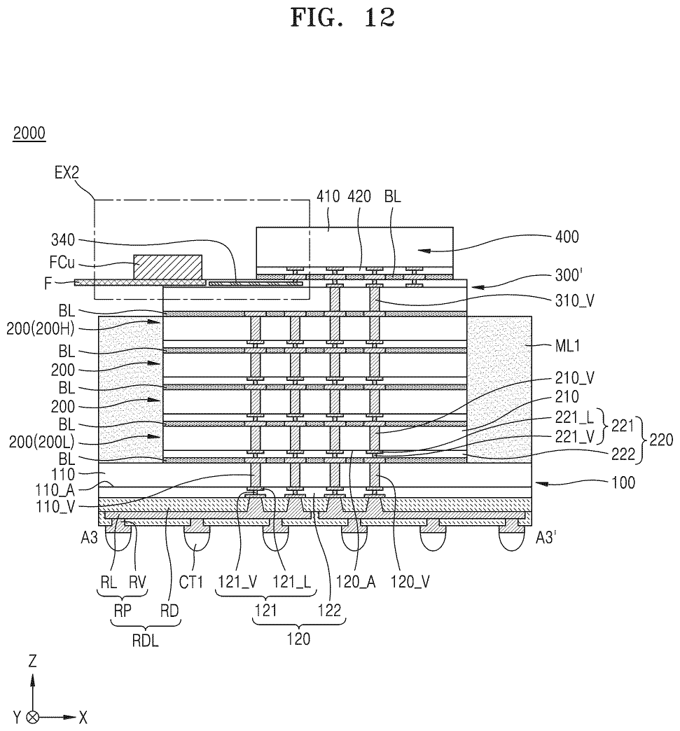

FIG. 11 is a schematic plan view of a semiconductor package 2000 according to an embodiment. FIG. 12 is a schematic cross-sectional view of the semiconductor package 2000 of FIG. 11 taken along a line A3-A3′ of FIG. 11. FIG. 13 is a schematic enlarged view illustrating a region EX2 of the semiconductor package 2000 of FIG. 12.

Most of the components forming the semiconductor package 2000 described below and the materials of the components are substantially the same as or similar to those described above with reference to FIG. 2. Therefore, for convenience of explanation, the differences between the semiconductor package 2000 of FIG. 12 and the semiconductor package 1000 of FIG. 2 are mainly described.

Referring to FIGS. 11 and 12, the semiconductor package 2000 may include a PIC chip 300′. The PIC chip 300′ may include a third substrate 310, a third wiring structure 320, and a plurality of waveguides 340.

The PIC chip 300′ may further include a second groove 300′_G extending from an upper surface and a side surface of the PIC chip 300′ to the inside of the PIC chip 300′. For example, the interior of the second groove 300′_G may be open towards both the side surface and the upper surface of the PIC chip 300′. In some embodiments, the second groove 300′_G may be referred to as a V-groove.

In some embodiments, the second groove 300′_G may be adjacent to the waveguides 340. For example, an end portion of the waveguides 340 may be exposed to the outside through the second groove 300′_G. For example, the vertical level of the bottom surface of the second groove 300′_G may be lower than that of the waveguides 340.

In some embodiments, the optical fibers F may be attached to the interior of the second groove 300′_G. For example, the optical fibers F may be attached to the interior of the second groove 300′_G by a clear adhesive member located between the PIC chip 300′ and the optical fibers F.

In some embodiments, the semiconductor package 2000 may further include an optical fiber lead FCu. The optical fiber lead FCu may cover upper portions of the optical fibers F and protect the optical fibers F. In addition, the optical fiber lead FCu may fix the positions of the optical fibers F.

In some embodiments, end portions of the optical fibers F may face end portions of the waveguides 340. The vertical levels of the optical fibers F may be the same as the vertical levels of the waveguides 340. The optical fibers F may be optically connected to the waveguides 340.

Each waveguide 340 may further include an edge coupler 340_EC located on an end portion of each waveguide 340. For example, the edge coupler 340_EC may be on an end portion of each waveguide 340 that faces the optical fibers F. The optical fibers F may be optically connected to the waveguides 340 through the edge coupler 340_EC. For example, the other end portion of the waveguides 340 may be connected to the photonic component 340_P.

In some embodiments, an end portion of each waveguide 340, on which the edge coupler 340_EC of each waveguide 340 is located, may not overlap the EIC chip 400 in the vertical direction (the Z direction). In some embodiments, the edge coupler 340_EC of each waveguide 340 may be exposed to the outside through the second groove 300′_G.

In some embodiments, the semiconductor package 2000 may further include the second molding layers (ML2a of FIG. 4, ML2b of FIG. 5, and ML2c of FIG. 6) described above.

The waveguides 340 may be optically connected to the optical fibers F through the edge coupler 340_EC, and thus, the bandwidth of the semiconductor package 2000 may increase. For example, each waveguide 340 may input/output multi-wavelength optical signals to/from the PIC chip 300′.

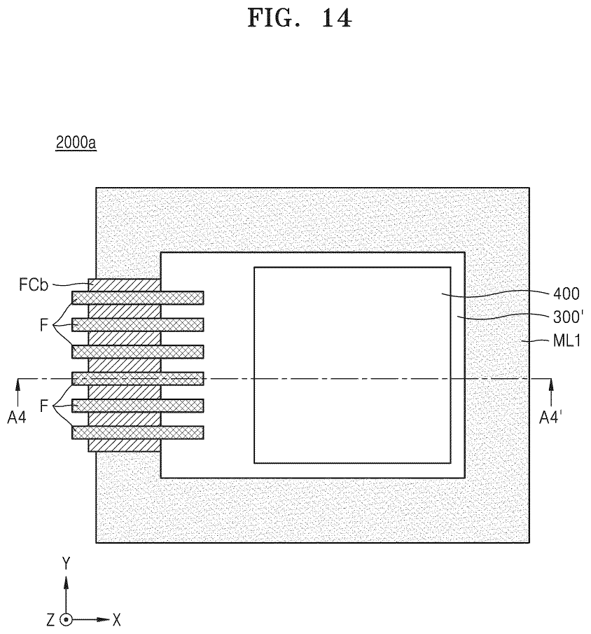

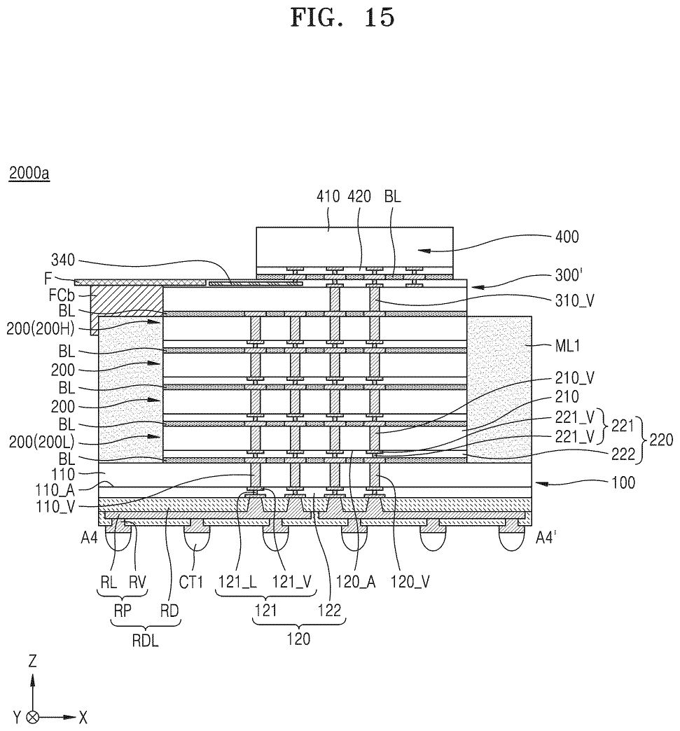

FIG. 14 is a schematic plan view of a semiconductor package 2000a according to an embodiment. FIG. 15 is a schematic cross-sectional view of the semiconductor package 2000a of FIG. 14 taken along a line A4-A4′ of FIG. 14.

Most of the components forming the semiconductor package 2000a described below and the materials of the components are substantially the same as or similar to those described above with reference to FIG. 11. Therefore, for convenience of explanation, the differences between the semiconductor package 2000a of FIG. 14 and the semiconductor package 2000 of FIG. 11 are mainly described.

Referring to FIGS. 14 and 15, the semiconductor package 2000a may include optical fibers F and an optical fiber lead FCb supporting the optical fibers F.

The optical fiber lead FCb may be located under the optical fibers F, providing support to the optical fibers F from below. In some embodiments, the optical fiber lead FCb may be on the first molding layer ML1 and in contact with the lower surfaces of the optical fibers F. FIG. 15 illustrates the optical fiber lead FCb contacting the side surface of the PIC chip 300′ and the side surface of the first molding layer ML1, but the shape of the optical fiber lead FCb is not limited thereto.

Because lower portions of the optical fibers F are supported by the optical fiber lead FCb, the shaking of the optical fibers F in the vertical direction (the Z direction) may be controlled, thereby reducing coupler loss occurring between the optical fibers F and the waveguides 340.

While the inventive concept has been particularly shown and described with reference to embodiments thereof, it will be understood that various changes in form and details may be made therein without departing from the spirit and scope of the invention.

What is claimed is:

1. A semiconductor package comprising:
a first semiconductor chip;
a plurality of second semiconductor chips stacked on the first semiconductor chip;
a first molding layer on the first semiconductor chip and surrounding side surfaces of the plurality of second semiconductor chips;
a photonic integrated circuit (PIC) chip on an uppermost second semiconductor chip among the plurality of second semiconductor chips; and
an electronic integrated circuit (EIC) chip on the PIC chip,
wherein an upper surface of the first molding layer is coplanar with an upper surface of the uppermost second semiconductor chip.

2. The semiconductor package of claim 1, wherein a width of the PIC chip is less than a width of the first molding layer.

3. The semiconductor package of claim 2, wherein the plurality of second semiconductor chips have the same width, and
wherein a width of the PIC chip is the same as the width of each of the plurality of second semiconductor chips.

4. The semiconductor package of claim 1, wherein a width of the EIC chip is less than a width of the PIC chip.

5. The semiconductor package of claim 1, wherein the PIC chip further comprises a plurality of waveguides and a through via penetrating the PIC chip,
wherein the plurality of waveguides are arranged in the PIC chip adjacent to an upper surface of the PIC chip, and
wherein at least a portion of each of the plurality of waveguides does not overlap the EIC chip in a vertical direction.

6. The semiconductor package of claim 5, further comprising a plurality of optical fibers optically and respectively connected to the plurality of waveguides of the PIC chip.

7. The semiconductor package of claim 5, wherein each of the plurality of waveguides further comprises a grating coupler, and
wherein the grating coupler of each of the plurality of waveguides does not overlap the EIC chip in the vertical direction.

8. The semiconductor package of claim 7, wherein the plurality of waveguides comprise a first waveguide and a second waveguide, and
wherein the grating coupler of the first waveguide is spaced apart from the grating coupler of the second waveguide with the EIC chip therebetween.

9. The semiconductor package of claim 5, wherein each of the plurality of waveguides further comprises an edge coupler arranged on an end portion of each of the plurality of waveguides, and
wherein the end portion of each of the plurality of waveguides, on which the edge coupler is located, does not vertically overlap the EIC chip.

10. The semiconductor package of claim 1, wherein each of the plurality of second semiconductor chips comprises a dynamic random access memory (DRAM) cell, and
wherein the first semiconductor chip is configured to control the DRAM cell of each of the plurality of second semiconductor chips.

11. The semiconductor package of claim 10, wherein the PIC chip is configured to convert an optical signal into an electrical signal and an electrical signal into an optical signal, and
wherein the EIC chip is configured to interconnect the PIC chip with the first semiconductor chip.

12. The semiconductor package of claim 1, wherein the plurality of second semiconductor chips have the same thickness.

13. The semiconductor package of claim 1, further comprising a heat sink on the EIC chip.

14. A semiconductor package comprising:
a first semiconductor chip;
a plurality of second semiconductor chips stacked on the first semiconductor chip;
a first molding layer on an upper portion of the first semiconductor chip and surrounding side surfaces of the plurality of second semiconductor chips;
a photonic integrated circuit (PIC) chip on an uppermost second semiconductor chip among the plurality of second semiconductor chips;
a second molding layer on the first molding layer and surrounding a portion of the PIC chip; and
an electronic integrated circuit (EIC) chip on the PIC chip,
wherein an upper surface of the first molding layer is coplanar with an upper surface of the uppermost second semiconductor chip, and
wherein the first molding layer contacts the second molding layer.

15. The semiconductor package of claim 14, wherein the second molding layer surrounds a side surface of the PIC chip, and
wherein an upper surface of the second molding layer is coplanar with an upper surface of the PIC chip.

16. The semiconductor package of claim 14, wherein the PIC chip comprises a plurality of waveguides,
wherein the second molding layer surrounds the PIC chip and the EIC chip and comprises a groove extending from an upper surface of the second molding layer to the inside of the second molding layer,
wherein the groove is on an upper portion of the plurality of waveguides of the PIC chip, and
wherein an upper surface of the second molding layer is coplanar with an upper surface of the EIC chip.

17. The semiconductor package of claim 16, wherein a waveguide of the plurality of waveguides of the PIC chip comprises a grating coupler, and
wherein the groove of the second molding layer is on an upper portion of the grating coupler of the waveguide.

18. The semiconductor package of claim 14, wherein a width of the second molding layer is the same as a width of the first molding layer, and
wherein a width of the PIC chip is the same as a width of each of the plurality of second semiconductor chips.

19. A semiconductor package comprising:
a first semiconductor chip;
a plurality of second semiconductor chips stacked on the first semiconductor chip, the plurality of second semiconductor chips each comprising a dynamic random access memory (DRAM) cell, each of the plurality of second semiconductor chips having the same thickness as each other;
a first molding layer on an upper portion of the first semiconductor chip and surrounding side surfaces of the plurality of second semiconductor chips;
a photonic integrated circuit (PIC) chip on an uppermost second semiconductor chip among the plurality of second semiconductor chips, the PIC chip configured to convert an optical signal into an electrical signal and an electrical signal into an optical signal;
a second molding layer on the first molding layer and contacting a portion of the PIC chip; and
an electronic integrated circuit (EIC) chip on the PIC chip and configured to interconnect the PIC chip with the first semiconductor chip,
wherein the first semiconductor chip is configured to control the DRAM cell of each of the plurality of second semiconductor chips,
wherein a width of the EIC chip is less than a width of the PIC chip,
wherein the width of the PIC chip is less than a width of the first molding layer, and
wherein an upper surface of the first molding layer is coplanar with an upper surface of the uppermost second semiconductor chip.

20. The semiconductor package of claim 19, wherein the first molding layer contacts the second molding layer and the first molding layer comprises the same material as the second molding layer,
wherein a side surface of the second molding layer is coplanar with a side surface of the first molding layer, and
wherein a thickness of the second molding layer is the same as a thickness of the PIC chip.
